(19) United States
(12) Patent Application Publication
(10) Pub. No.: US 2010/0118602 A1
(43) Pub. Date: May 13, 2010

(54) DOUBLE SOURCE LINE-BASED MEMORY ARRAY AND MEMORY CELLS THEREOF

(75) Inventors: Andrew John Carter, Minneapolis, MN (US); Yiran Chen, Eden Prairie, MN (US); Yong Lu, Rosemount, MN (US); Harry Hongyue Liu, Maple Grove, MN (US)

Correspondence Address: Fellers, Snider, Blankenship, Bailey & Tippens, PC;(Seagate Technology LLC), 100 North Broadway, Suite 1700, Oklahoma City, OK, 73102-8820, US

(73) Assignee: SEAGATE TECHNOLOGY LLC, Scotts Valley, CA (US)

(21) Appl. No.: 12/270,056

(22) Filed: Nov. 13, 2008

(51) Int. Cl. G11C 11/14

(52) U.S. Cl. 365/171

(57) ABSTRACT

A memory array includes a plurality of first and second source, lines overlapping a plurality of bit lines, and a plurality of magnetic storage elements, each coupled to a corresponding first and second source line and to a corresponding bit line. Current may be driven, in first and second directions, through each magnetic element, for example, to program the elements. Diodes may be incorporated to avert sneak paths in the memory array. A first diode may be coupled between each magnetic element and the corresponding first source line, the first diode being biased to allow read and write current flow through the magnetic element, from the corresponding first source line; and a second diode may be coupled between each magnetic element and the corresponding second source line, the second diode being reverse-biased to block read and write current flow through the magnetic element, from the corresponding second source line.

### BACKGROUND

Magnetic random access memory (MRAM) typically employs an array that includes a plurality of intersecting word, or source, and bit lines and a plurality of magnetic storage elements, wherein each magnetic storage element includes a magnetic tunneling junction (MTJ) and is located at, or near, an intersection, or crossing, of a source line with a bit line. Programming a particular magnetic element in the array relies upon driving current through those bit and source lines that cross in proximity to that element. The crossing currents produce a magnetic field of a magnitude sufficient to switch a magnetization orientation of the free layer of the magnetic storage element in order to program, or write, the element as a logical ‘0’ or ‘1’, depending upon the direction of the current flow through the bit line.

Because this external magnetic field is not a localized phenomenon, it may be appreciated that a drawback of the conventional MRAM array can be the inadvertent disturbance or writing of magnetic storage elements which are nearby the intended magnetic storage element. In order to overcome this drawback, memory arrays can incorporate magnetic storage elements, which have the current perpendicular to plane (CCP) configuration, so that the spin transfer phenomenon can be employed. Thus, rather than relying upon an external magnetic field for programming, the magnetic storage element may be programmed via current flow directly therethrough; current that flows in a first direction through the element writes a ‘0’ and current that flows in a second, opposite, direction writes a ‘1’. A current having a smaller magnitude than the write current may be driven through the magnetic storage element in either direction to read the element. The present disclosure pertains to configurations of memory arrays and magnetic memory cells thereof in which the spin transfer phenomenon may be employed for writing.

### SUMMARY

A memory array, according to embodiments of the present disclosure, includes a plurality of magnetic storage elements, which are each coupled to a corresponding bit line of the array and to a corresponding pair of source lines of the array. Current may be driven through each magnetic storage element, in a first direction, from a first source line of the corresponding pair to a bit line of the corresponding pair, for example, to write a ‘0’; and current may be driven through each magnetic storage element, from the corresponding bit line to the corresponding second source line, for example, to write a ‘1’. A current of lower magnitude, may be driven in either of the aforementioned directions, through each magnetic storage element, to read the element.

According to some embodiments, each memory cell of the array includes one the plurality of magnetic storage elements and a pair of diodes. A first diode of each pair may be coupled in series between the corresponding magnetic storage element and the corresponding first source line, wherein the first diode is biased to allow read and write current to flow through the magnetic element, from the corresponding first source line. A second diode of each pair may be coupled in series between the corresponding magnetic storage element and the corresponding second source line, wherein the second diode is reverse-biased to block read and write current from flowing through the magnetic element, from the corresponding second source line.

### BRIEF DESCRIPTION OF THE DRAWINGS

The following drawings are illustrative of particular embodiments of the disclosure and therefore do not limit the scope of the invention. The drawings are not to scale (unless so stated) and are intended for use in conjunction with the explanations in the following detailed description. Embodiments of the disclosure will hereinafter be described in conjunction with the appended drawings, wherein like numerals denote like elements.

FIG. 1 is a schematic of a rudimentary memory array.

FIG. 2 is a schematic of a memory array, according to some embodiments of the present disclosure.

FIG. 3 is a simplified section view through a memory cell, which may be incorporated by the array of FIG. 2.

FIG. 4 is a flow chart outlining some methods of the present disclosure.

### DETAILED DESCRIPTION

The following detailed description is exemplary in nature and is not intended to limit the scope, applicability, or configuration of the invention in any way. Rather, the following description provides practical illustrations for implementing exemplary embodiments.

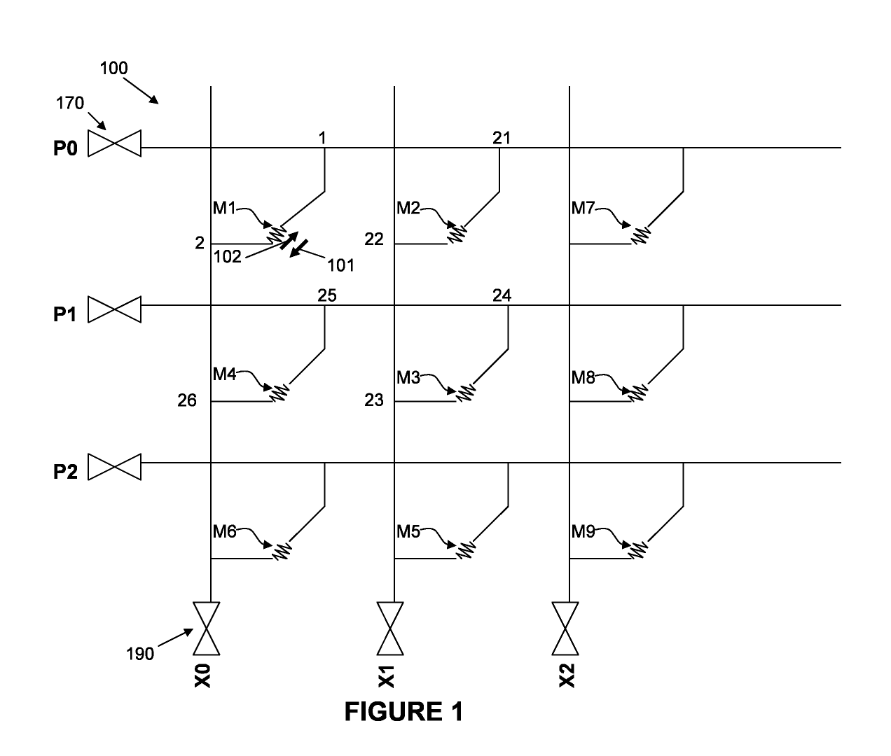

FIG. 1 is a schematic of a rudimentary N×N memory array 100. FIG. 1 illustrates array 100 including a plurality of sourcelines P0, P1, P2, a plurality of bit lines X0, X1, X2, and a plurality of magnetic storage elements M1-M9, each of which are located at an intersection of a source and bit line. FIG. 1 further illustrates a switch 170 coupled to an end of each source line P0, P1, P2 and a switch 190 coupled to an end of each bit line X0, X1, X2. For ease of illustration, only a portion of array 100 is shown in FIG. 1, but it should be appreciated that that each source line P0, P1, P2 includes another switch 170 at an opposite end thereof and, likewise, each bit line X0, X1, X2 includes another switch 190 at an opposite end thereof. Furthermore, according to FIG. 1, N=3, but it should be appreciated that, for MRAM applications, N is typically on the order of 1,000.

The operation of array 100 will now be described, with reference to magnetic storage element M1, which is coupled to source line P0, at a terminal connection point 1, and to bit line X0, at a terminal connection point 2. When source line P0 is switched to a positive voltage and bit line X0 is switched to ground, a voltage potential is established to drive current through magnetic storage element M1 in a first direction 101 from source line P0 to bit line X0. Depending upon the magnitude of the voltage, to which source line P0 is switched, the current flowing in first direction 101 will either write or read magnetic storage element M1. However, due to other connections between source line P0 and bit line X0, current may also flow through magnetic storage elements M2-M9 as well, along what are known as ‘sneak paths’. For example, the voltage potential, which is established between source line P0 and bit line X0 and intended to drive current through magnetic storage element M1, can also drive current through magnetic storage element M2, from a terminal connection point 21 to a terminal connection point 22, and then through magnetic storage element M3, from a terminal connection point 23 to a terminal connection point 24, and then through magnetic storage element M4, from a terminal connection point 25 to a terminal connection point 26. With further reference to FIG. 1, it may be appreciated that the magnetic storage elements M5-M9 are also subject to current sneak paths when the voltage potential is established between source line P0 and bit line X0. Because the current sneak paths can render array 100 inoperative, the architecture needs to be modified to block the sneak paths.

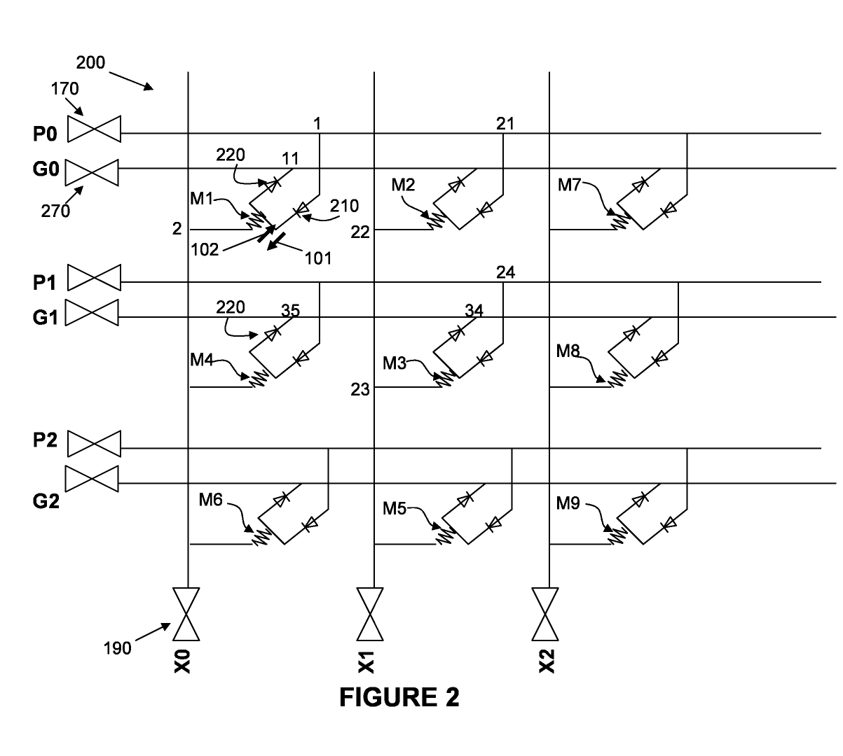

FIG. 2 is a schematic of a memory array 200, according to some embodiments of the present disclosure, which is configured to avoid the problem of current sneak paths. FIG. 2 illustrates array 200 including plurality of source lines P0, P1, P2 paired with a plurality of second source lines G0, G1, G2, wherein each pair of first and second source lines P0 and G0, P1 and G1, P2 and G2 overlaps each of bit lines X0, X1, X2. Each magnetic storage element M1-M9 is shown coupled between a corresponding first and second source line and a corresponding bit line such that current may be driven through each element in first direction 101, from the corresponding first source line to the corresponding bit line, and in a second direction 102, from the corresponding bit line to the corresponding second source line.

FIG. 2 further illustrates a first diode 210 of each of a plurality of pairs of diodes coupled in series between each magnetic storage element M1-M9 and the corresponding first source line P0, P1, P2, and a second diode 220 of each plurality of pairs coupled in series between each magnetic storage element M1-M9 and the corresponding second source line G0, G1, G2. Each first diode 210 allows current to be driven in first direction 101, and each second diode 220 allows current to be driven in second direction 102, as previously described; and each second diode 220 is reverse-biased to block current from flowing from each second source line G0, G1, G2 to each bit line X0, X1, X2, thereby preventing current sneak paths, as will be described in greater detail below.

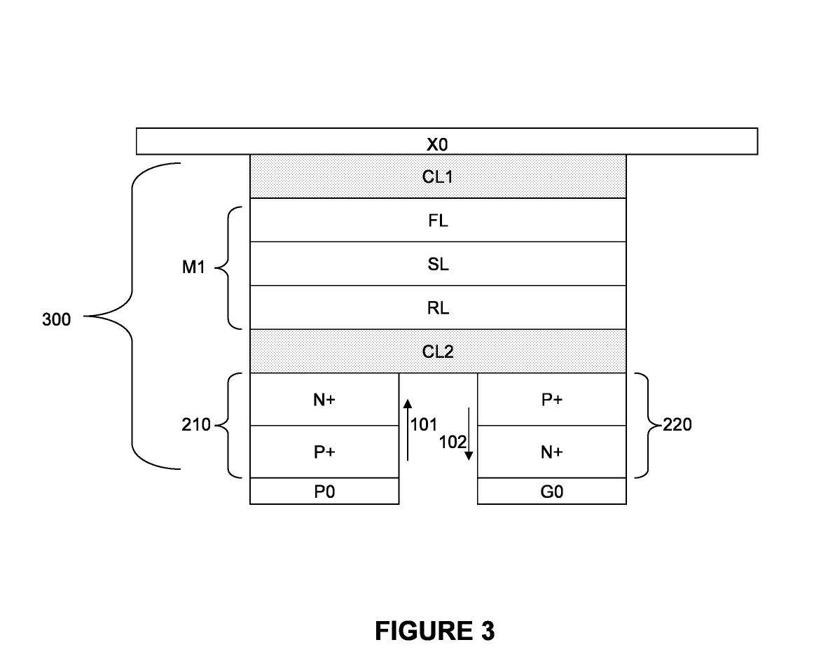

FIG. 3 is a simplified section view through a memory cell 300, according to some embodiments, which may be incorporated by array 200. FIG. 3 illustrates memory cell 300 including magnetic storage element M1, wherein a first contact layer CL1, for example, formed from platinum, couples element M1 to bit line X0, and wherein a second contact layer, for example, formed from tungsten, couples element M1 to first and second diodes 210, 220. FIG. 3 further illustrates first diode 210 being coupled between first source line P0 and second contact layer CL2, to allow current to flow in first direction 101, and second diode 220 being coupled between second source line G0 and second contact layer CL2, and being reversed-biased to block current from flowing in first direction 101, yet to allow current to flow in second direction 102. According to the illustrated embodiment, diodes 210, 220 are semiconductor silicon junction diodes, known to those skilled in the art, and magnetic storage element M1 includes a free layer FL, or soft ferromagnetic layer, separated by a spacer layer SL from a reference layer RL, such as is known to those skilled in the art. Element M1 may be a magnetic tunnel junction type or a spin valve type, in which the spin transfer phenomenon is employed for writing; and the layers of element M1 may be formed from any suitable material and by any suitable fabrication method. It should be noted that memory cell 300 may be representative of all the memory cells of array 200.

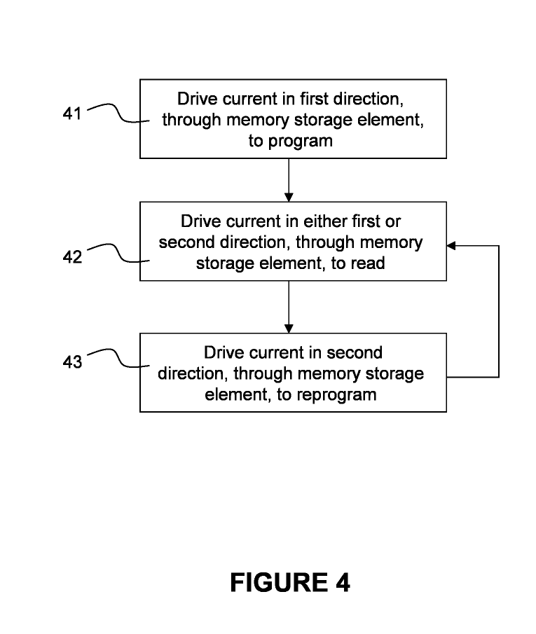

A method of operation for memory array 200 of FIG. 2 will now be described, in conjunction with the flow chart of FIG. 4; the description focuses on the memory cell of array 200, which includes magnetic storage element M1. According to an initial step 41, a write current is driven, in a first direction 101, through magnetic storage element M1, in order to program element M1, for example, to a logical ‘0’. The current is driven by establishing a first voltage potential across the memory cell. The first voltage potential may be established by setting first source line P0 to a positive voltage, via switch 170, and by setting bit line X0 to ground, via switch 190, so that write current flows from terminal connection point 1 to terminal connection point 2, in first direction 101, through magnetic storage element M1. Magnetic storage element M1 may be read, per step 42, by reducing the magnitude of the voltage to which first source line P0 is set in order to drive a lower magnitude current, in first direction 101, through element M1. Alternatively, the lower magnitude read current may be driven through element M1, in second direction 102, from terminal connection point 2 to a terminal connection point 11 with second source line G0, by setting bit line X0 to a positive voltage, via switch 190, and second source line G0 to ground, via switch 270. In order to re-program magnetic storage element M1, per step 43, for example, from ‘0’ to ‘1’, a larger magnitude write current is driven in second direction 102, by increasing the magnitude of the voltage to which bit line X0 is set. According to an exemplary embodiment, if the built-in voltage, or threshold voltage (Vₜ) of diodes 210, 220 is approximately 700 mV, and a 500 mV potential is required to write magnetic storage elements M1-M9, then array 200 requires a 1.2 V power supply.

With further reference to FIG. 2, it may be appreciated that current sneak paths are averted by the pair of diodes 210, 220 incorporated into each memory cell of array 200. For example, when a voltage potential is established between source line P0 and bit line X0 in order to drive a current, in first direction 101, through magnetic storage element M1, a current sneak path through magnetic storage elements M2, M3 and M4, which would extend from point 21 to point 22, through element M2, and then, along bit line X1, to point 23, and then to a point 34, through element M3, and then, along second source line G1, to a point 35, is blocked by the second diode 220, which is reverse-biased and connected in series between magnetic storage element M4 and second source line G1. Thus, the architecture of array 200 does not allow for connections, other than that intended, between the source line and the bit line that correspond to the intended memory cell. Furthermore, it may be appreciated that as long as the Vₜ of diodes 210, 220 is greater than zero the Vₜ need not be precisely controlled for effective operation of array 200.

Those skilled in the art will appreciate that an alternative architecture can employ a transistor within each memory cell to avert current sneak paths. However, due to the greater current carrying capacity, per unit area, of semiconductor diodes, the incorporation of a pair of diodes within each memory cell, according to preferred embodiments disclosed herein, may result in a more efficient use of area.

In the foregoing detailed description, embodiments of the disclosure have been described. These implementations, as well as others, are within the scope of the appended claims.

1. A memory array comprising:
a plurality of magnetic storage elements;
a plurality of bit lines extending in a first direction; and
a plurality of first and second source lines extending in a second direction and overlapping each of the bit lines;
wherein each of the magnetic elements is coupled to a corresponding first source line and second source line, and to a corresponding bit line, such that current can be driven in a first direction, through each of the magnetic elements, from the corresponding first source line to the corresponding bit line, and current can be driven in a second direction, through each of the magnetic elements, from the corresponding bit line to the corresponding second source line.

2. The array of claim 1, wherein each of the magnetic elements is programmed to a first state by current being driven therethrough in the first direction, and is programmed to a second state by current being driven therethrough in the second direction.

3. The array of claim 1, wherein a programmed state of each of the magnetic elements is read by current being driven therethrough in either of the first and second directions.

4. The array of claim 1, further comprising:
a plurality of first and second diodes; and
wherein each of the first diodes is coupled, in series, between a corresponding magnetic element and the corresponding first source line, each of the first diodes being biased to allow read and write current to flow to the corresponding bit line from the corresponding first source line; and
each of the second diodes is coupled, in series, between the corresponding magnetic element and the corresponding second source line, each of the second diodes being reverse-biased to block read and write current from flowing to the corresponding bit line from the corresponding second source line.

5. A method of operating a memory comprising:
establishing a first voltage potential across a memory cell of the memory, between a first source line of the memory and a bit line of the memory, in order to drive current, in a first direction, through the memory cell, the memory cell being coupled to the first source line and the to the bit line; and
establishing a second voltage potential across the memory cell, between a second source line of the memory and the bit line, in order to drive current, in a second direction, through the memory cell, the memory cell being further coupled to the second source line.

6. The method of claim 5, wherein:
establishing the first voltage potential comprises setting the first source line to a positive voltage and the bit line to ground; and
establishing the second voltage potential comprises setting the bit line to a positive voltage and the second source line to ground.

7. The method of claim 5, wherein one of the first and second voltage potentials is of a magnitude to program a magnetic storage element of the memory cell.

8. The method of claim 5, wherein both of the first and second voltage potentials is of a magnitude to program a magnetic storage element of the memory cell.

9. The method of claim 5, wherein one of the first and second voltage potentials is of a magnitude to read a programming of a magnetic storage element of the memory cell, without affecting the programming thereof.

10. A memory cell for a memory array comprising:
a first contact layer;
a second contact layer;
a first diode;
a second diode; and
a magnetic storage element coupled, by the second contact layer, to the first diode and to the second diode, the magnetic storage element being coupled in series between the first diode and the first contact layer, and being coupled in series between the second diode and the first contact layer;
wherein the first diode is biased to allow read and write current to flow through the magnetic storage element, toward the first contact layer; and
the second diode is reverse biased to block read and write current from flowing through the magnetic storage element, toward the first contact layer.
